(19) United States
(12) Patent Application Publication
(10) Pub. No.: US 2008/0116587 A1
(43) Pub. Date: May 22, 2008

(54) CONDUCTOR POLYMER COMPOSITE CARRIER WITH ISOPROPERTY CONDUCTIVE COLUMNS

(76) Inventor: Chun Ho Fan, Hong Kong (CN)

Correspondence Address: THELEN REID BROWN RAYSMAN & STEINER LLP, 2225 EAST BAYSHORE ROAD, SUITE 210, PALO ALTO, CA, 94303, US

(21) Appl. No.: 11/938,254

(22) Filed: Nov. 10, 2007

Related U.S. Application Data
(60) Provisional application No. 60/866,211, filed on Nov. 16, 2006.

(51) Int. Cl. H01L 23/495; H01L 21/00

(52) U.S. Cl. 257/778; 438/123; 257/E21.001

(57) ABSTRACT

A carrier comprises a metallic panel, a conductive column, a circuit, and an electrically insulating filling. The conductive column is within the panel and travels from a first surface to a second surface of the panel. The circuit is located on first surface of the panel and in communication with the column. The electrically insulating filling is located within sections of the metallic panel. The circuit and the column forms a three dimensional contiguous path with at most one interface in between.

### PRIORITY CLAIM

This application claims priority to and incorporates by reference U.S. Patent Application No. 60/866,211, filed Nov. 16, 2006, by inventor Chun-Ho Fan, entitled “Conductor Polymer Composite Carrier.”

### TECHNICAL FIELD

This invention relates to carriers and more particularly, but not exclusively, provides a carrier having at most one interface between a column and circuit.

### BACKGROUND

Electronic packaging is the process in which a semiconductor die is functionally disposed onto a composite structure, which together with the die is loosely referred to as an electronic package. Generally, the functions of the electronic package are to provide protection to the die and to enable its electrical interconnection with the printed circuit board. Typically, the package comprises a carrier (also known as a substrate) having electrical circuitry, and the die is functionally connected to bondpads on the carrier through processes such as wire-bonding. Afterwards, part of the die and/or substrate is covered (sometimes with a polymer) for protection purposes.

For a package to be effective, it must among other factors exhibit the appropriate performance, reliability and cost factors. In general, the carrier has a significant effect on the performance of the package by altering its form factor (number of IO per area), signal impedance (particularly for high frequency applications), and/or ability to dissipate heat.

To achieve favorable form factors (i.e. large IO for a given footprints), a route-able substrate is generally used particularly for IO counts exceeding 100, and for this class of application, there are generally two types of area-array carriers available.

Accordingly, a new carrier is needed with improved performance, reliability and cost factors.

### SUMMARY OF THE INVENTION

Embodiments of the invention provide an area-array carrier, herein referred to as the Conductor Polymer Composite Carrier (CPCC), which may offer improved performance, reliability and cost factors.

Existing substrates utilizes multiple process steps (such as via hole drilling, multiple plating and printing) to accomplish three-dimensional routing of the electrical signal within the carrier (FIG. 1), and the resulting conductive trace typically lacks the characteristics required to achieve a low overall electrical impedance. Specifically, the presence of solid conductive columns allow for a lower electrical resistance, but to achieve this column, substrates typically need to utilize multiple processing steps that consequently adds multiple interfaces between a conductive column 130 and a signal distribution layer (circuit plane) 110 and 120. Each interface increases the cost, decreases the overall reliability (increasing risk of delamination), as well as increases the overall electrical resistance.

Embodiments of the invention provide a Conductor Polymer Composite Carrier (CPCC) whereby the circuit plane is separated from the conductive column of the same material by zero interface (i.e. contiguous material) and/or by at most one interface. As at least some of the material of the circuit plane is substantially identical with that of the conductive column, this structure is herein referred to as an Isoproperty 3D Trace. Generally, the zero-interface column is important for power connections while the single-interface column is important for signal propagation with tight line-pitch requirements. The columns may be square and/or circular (or other shapes), and the trace can form different patterns on the substrate depending on the application. For example, patterns for fully-populated I/O, three-dimensional stacking, isolated power-ring, and/or embedded passives can be easily formed through embodiments of the present invention. The resulting CPCC substrate can become part of an electronic package by functionally disposing the die onto the surface of the substrate, functionally connecting the die to the circuitry through wire-bonding or flip-chip bonding, and then finally by covering part or all of the die's surface through glob-top, molding or any other similar processes known in the arts.

Embodiments of the present invention also provide methods to cost effectively obtain the CPCC substrate. One embodiment comprises:
1. Pattern-passivation: This is to allow for the creation of etching resists on a metallic panel so that a subsequent etching process can produce the desired planar circuit patterns (herein referred to as the circuit plane)
2. Removal: This is to allow for the removal of materials (via etching) not protected by the pattern-passivation in step 1. This step allows for the formation of the conductive columns and the die-attach paddle.
3. Filling: This is to selectively give strength to portions of the panel that has been etched through the step above. This also serves the function of passivation against further etching processes.
4. Removal: This final etching process enables the creation of the desired planar circuit pattern for zero-interface substrates, thereby forming a three dimensional contiguous path with at most one interface in between.

Another embodiment comprises:
1. Pattern-passivation: This is to allow for the creation of etching resists on a metallic panel so that a subsequent etching process can produce the desired planar circuit patterns (herein referred to as the circuit plane). In an embodiment, this includes depositing etching resistant materials on a first and second side of a metallic panel.
2. Filling: This is to form a layer of etching mask on the circuit-plane side (e.g., first side).
3. Removal: This is to allow for the removal of materials (via etching) not protected by the pattern-passivation in step 1 (e.g., the second side not having etching resists thereon). This step allows for the formation of the conductive columns and the die-attach paddle. The conductive column travels from the first surface to the second surface
4. Filling: This is to selectively give strength to portions of the panel that has been etched through the step above. In an embodiment, filling includes filling in removed sections of the panel with an electrically insulating material at the second side.
5. Etching mask removal: This is to remove the etching mask introduced at step 2. This reveals a circuit on the first side that is in communication with a column, thereby forming a three dimensional contiguous path with one interface in between.

These three basic steps of pattern-passivation, Removal and Filling can be achieved through a multitude of processes that are known in the arts. For example, to accomplish the pattern-passivation in step 1, a photo-mask, an electroplated metal barrier such as nickel and/or gold, or any other processes that are known in the arts may be used. Once the pattern-passivation is accomplished, the Removal may be accomplished through etching process that are known in the arts including but not limited to wet-etching and dry-etching. Likewise, the Filling step can be accomplished through molding (including injection molding as well as the various variations thereof) with polymer material, and/or a glob-top process and/or a printing process and/or any other processes that are known in the arts.

### DESCRIPTION OF DRAWINGS

Non-limiting and non-exhaustive embodiments of the present invention are described with reference to the following figures, wherein like reference numerals refer to like parts throughout the various views unless otherwise specified.

FIG. 1-Schematic of via structures used in a prior art;

FIG. 2a-Schematic showing the result of the pattern-passivation step;

FIG. 2b-Schematic showing the result after the Removal step;

FIG. 2c-Schematic showing the result after the Filling step;

FIG. 2d-Schematic showing the result after the final Removal step;

FIG. 3-Isometric and cut-away view of a fully-populated circuit pattern;

FIG. 4-Schematic showing a circuit pattern with circular I/O pads and multiple die-attach paddles;

FIG. 5-Schematic showing a circuit pattern with embedded passive components;

FIG. 6-Schematic showing the utilization of the CPCC substrate in a flip-chip package; and

FIG. 7-Schematic showing the utilization of the CPCC substrate in three-dimensional stacked configuration.

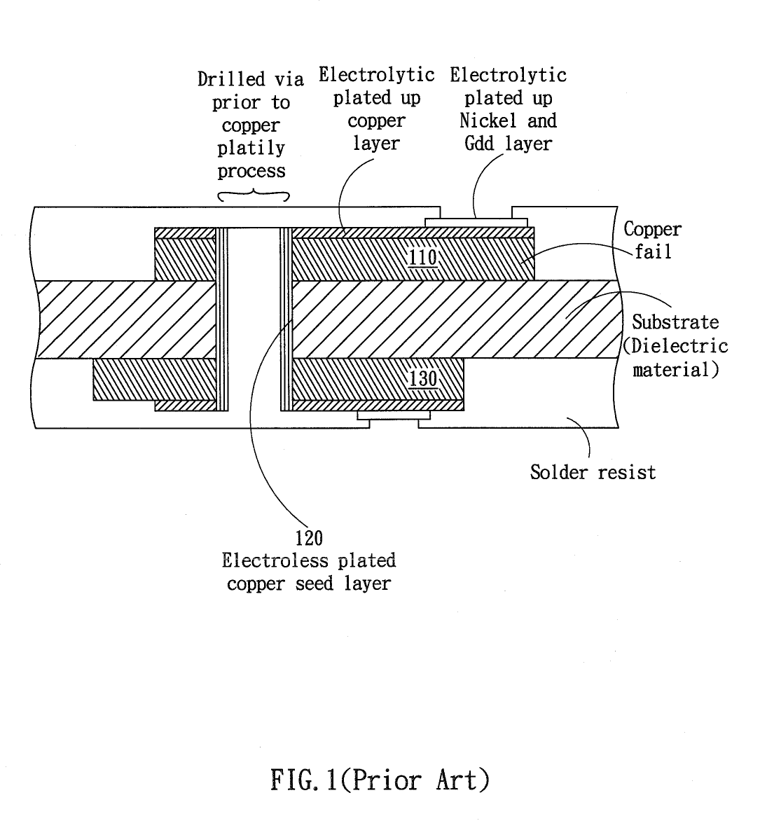

### DETAILED DESCRIPTION

The following description is provided to enable any person of ordinary skill in the art to make and use the invention and is provided in the context of a particular application. Various modifications to the embodiments are possible, and the generic principles defined herein may be applied to these and other embodiments and applications without departing from the spirit and scope of the invention. Thus, the invention is not intended to be limited to the embodiments and applications shown, but is to be accorded the widest scope consistent with the principles, features and teachings disclosed herein.

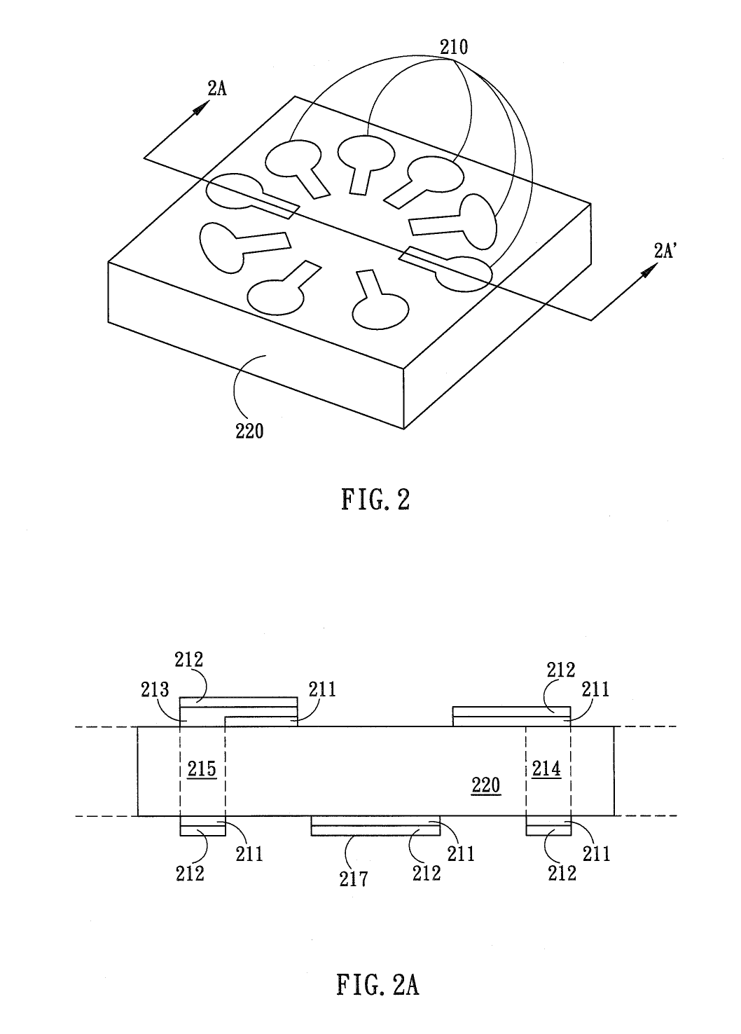

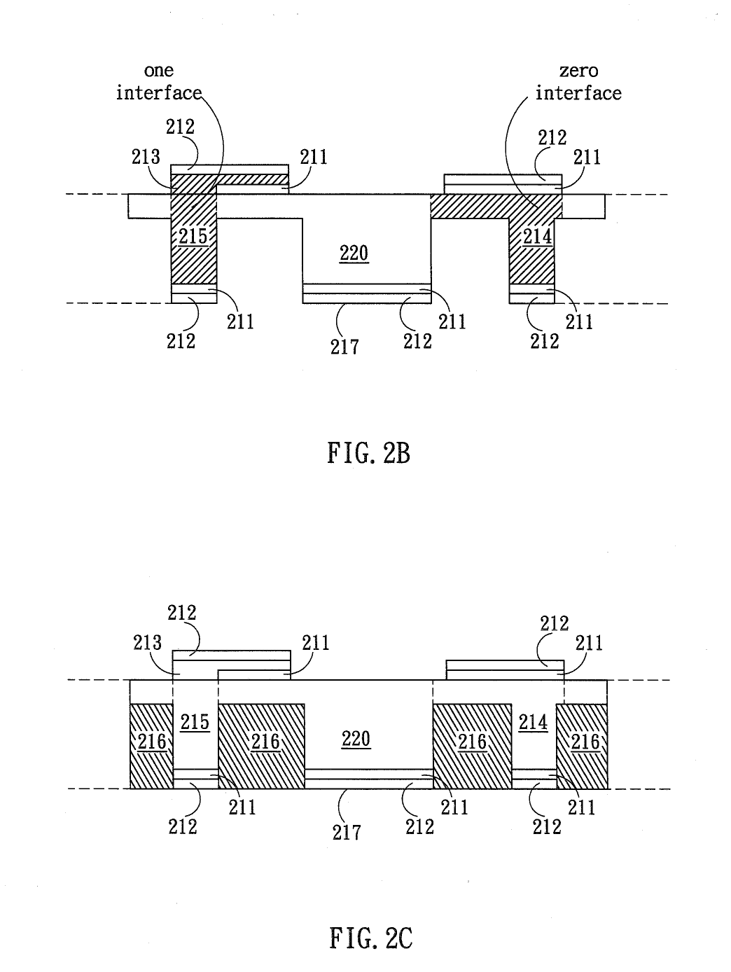

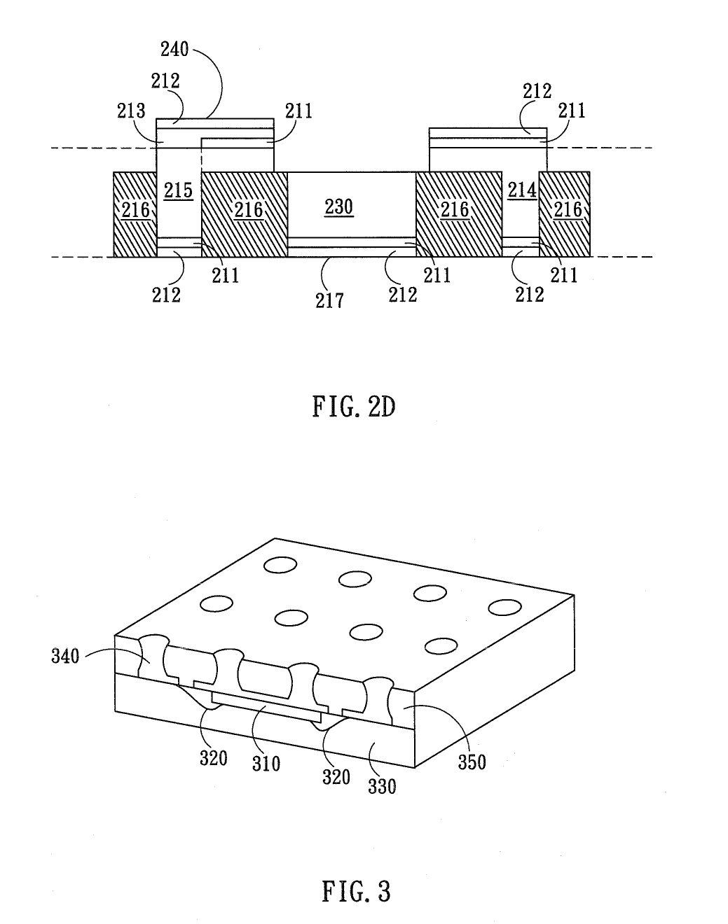

FIG. 2 shows the one process to form the Isoproperty 3-D Traces. FIG. 2a shows the formation of pattern-passivation 210 on a metallic sheet 220 (for example, copper). This pattern-passivation comprises of an etching resistant metal, like nickel 211 and/or gold 212, along with and the plating of material with the same chemical makeup as the metallic panel 213 (for example copper). The pattern-passivation defines the desired planar circuit pattern (herein referred to as the Circuit Plane), location of the subsequently formed columns 214, 215 and location of the die-attach paddle 217. As shown in FIG. 2b, the panel is then subjected to Removal process (i.e., etching) at the bottom to form columns with zero interface 214 and with one interface 215. Following this Removal step, selective regions of the bottom-side 216 and are covered with polymer (Filling process), as shown in FIG. 2c. Following this Filling process, the circuit-plane side is subjected to a Removal process (i.e., etching) to form the circuitry 230 and the die-attach cavity 240.

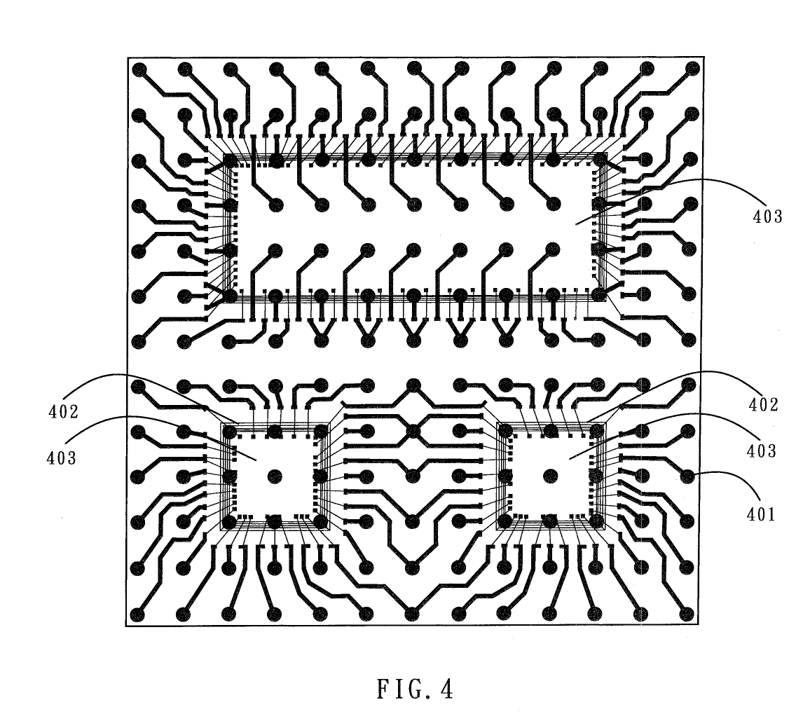

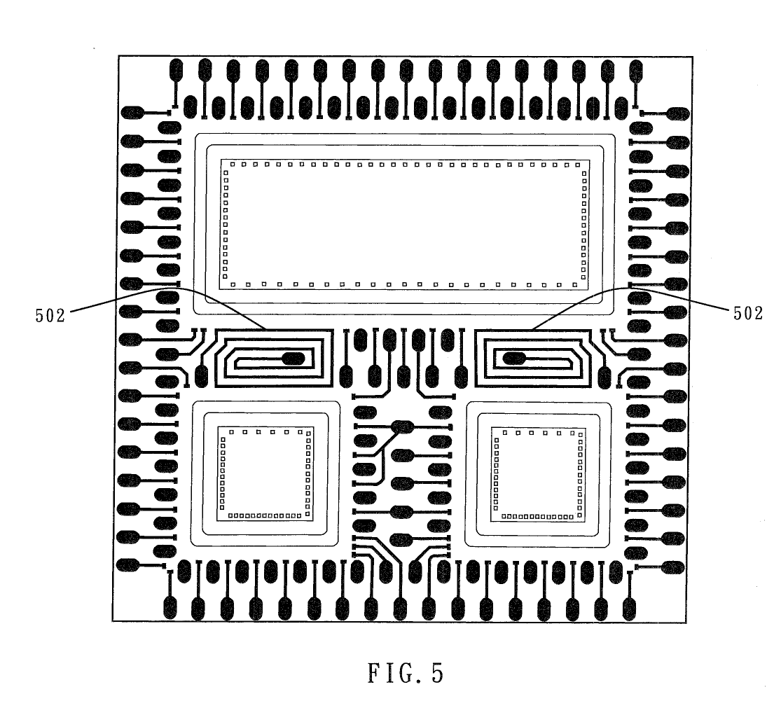

The above process enables the creation of substrates with different circuit patterns. For example, FIG. 3 is a cut-away view of a basic fully-populated, in-line, square I/O pattern showing the presence of a die 310 with die-attach wires 320, insulating die-attach material 330, conductive column 340, and filled-in polymer 350. FIG. 4 illustrates yet another pattern using circular I/O pads 401, segmented power-ring 402, and multiple die-attach paddles 403. Yet another pattern is shown in FIG. 5 with built-in inductors 502.

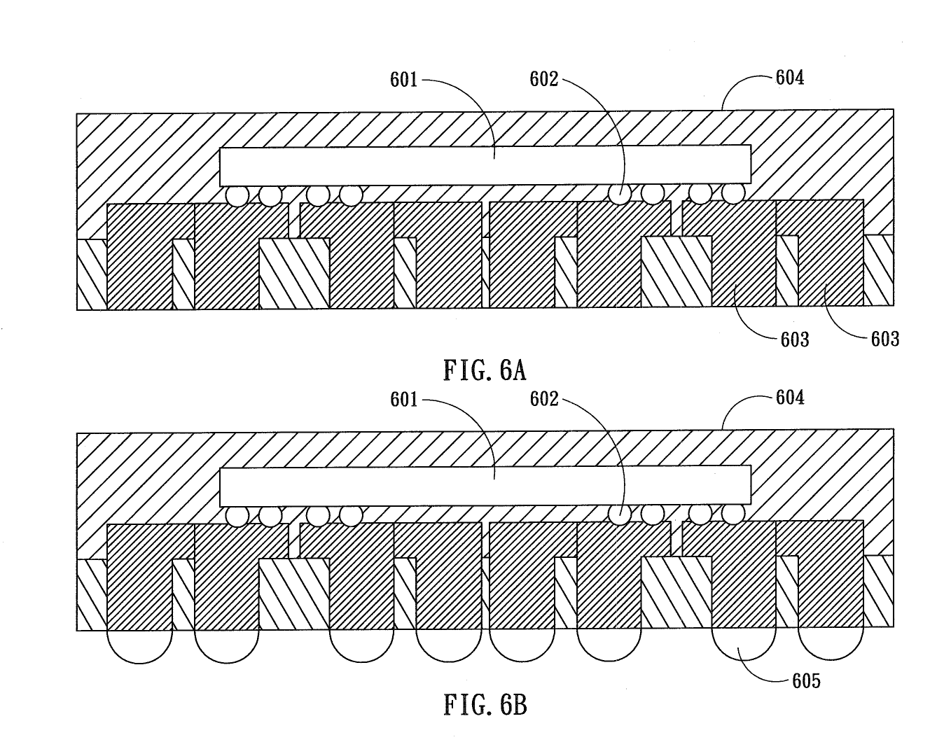

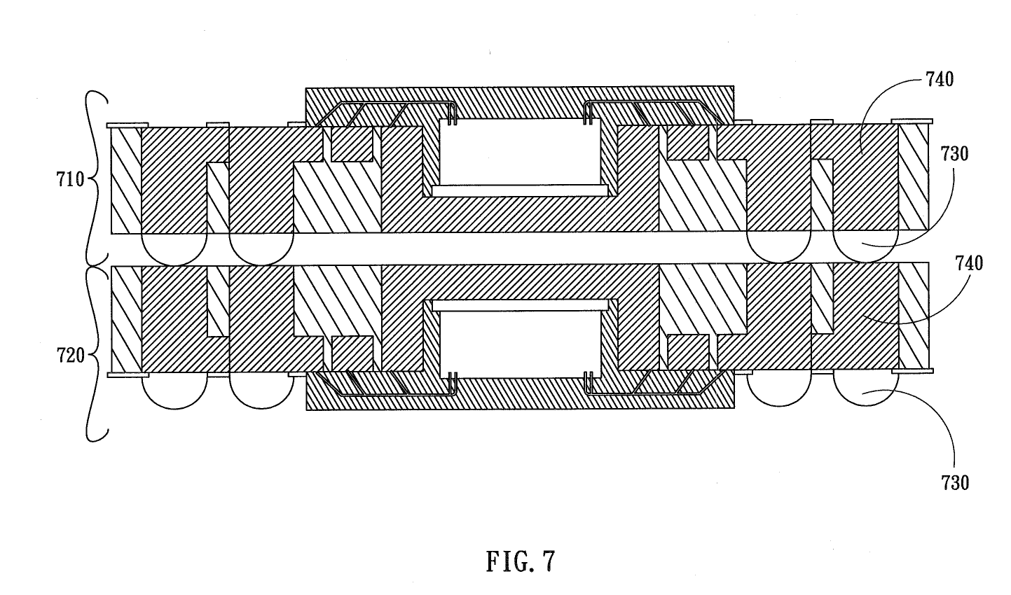

FIG. 6a shows the utilization of the CPCC substrate in a flip-chip electronic package containing the exposed-back die 601, the flip-chip balls 602, the LGA 603 and the die-protective polymer 604. FIG. 6b shows the utilization of the CPCC substrate in a flip-chip BGA package containing the additional solder balls 605. Finally, a pattern for three-dimensional stacking is shown in FIG. 7, where on multiple substrates 710 and 720, the solder balls 730 are placed onto the columns 740.

The foregoing description of the illustrated embodiments of the present invention is by way of example only, and other variations and modifications of the above-described embodiments and methods are possible in light of the foregoing teaching. The embodiments described herein are not intended to be exhaustive or limiting. The present invention is limited only by the following claims.

What is claimed is:

1. A method of forming a carrier, comprising:
forming etching resists on a metallic panel;
forming a conductive column through removal of sections of the panel not having etching resists thereon, the column traveling from a first surface to a second surface of the panel;
filling in removed sections of the panel with an electrically insulating material; and
etching a circuit onto the first surface of the panel;
and wherein the circuit and the column forms a three dimensional contiguous path with at most one interface in between.

2. The method of claim 1, further comprising forming a die-attach paddle on the second surface through the removal of sections of the panel not having etching resists thereon.

3. The method of claim 1, wherein the circuit and the column forms a three-dimensional contiguous path with no interface in between.

4. The method of claim 1, further comprising coupling a die to the carrier.

5. The method of claim 4, further comprising covering a part of the die.

6. The method of claim 5, further comprising placing a solder ball on the column and stacking multiple carriers together such that the columns are in communication through the solder balls.

7. The method of claim 5, further comprising place a solder ball on the column.

8. The method of claim 1, wherein a common material of the circuit and column are in communication.

9. The method of claim 1, wherein the column is solid.

10. A method of forming a carrier, comprising:
depositing etching resistant materials on a first and second side of a metallic panel;
depositing an etching mask on a first side of the panel;
forming a conductive column traveling from the first surface to a second surface of the panel through removal of sections of the panel from the second side not having etching resists thereon;
filling in removed sections of the panel with an electrically insulating material at the second side; and
removing the etching mask to reveal a circuit on the first side in communication with the column; and
wherein the circuit and the column forms a three dimensional contiguous path with one interface in between.

11. The method of claim 10, further comprising forming a die-attach paddle on the second surface through the removal of sections of the panel not having etching resists thereon.

12. The method of claim 10, further comprising coupling a die to the carrier.

13. The method of claim 12, further comprising covering a part of the die.

14. The method of claim 13, further comprising placing a solder ball on the column and stacking multiple carriers together such that the columns are in communication through the solder ball.

15. The method of claim 13, further comprising place a solder ball on the column.

16. The method of claim 10, wherein a common material of the circuit and column are in communication.

17. The method of claim 10, wherein the column is solid.

18. A carrier, comprising:
a metallic panel;
a conductive column within the panel from a first surface to a second surface of the panel;
a circuit on first surface of the panel and in communication with the column; and
an electrically insulating filling within sections of the metallic panel; and
wherein the circuit and the column forms a three dimensional contiguous path with at most one interface in between.

19. The carrier of claim 18, further comprising a die-attach paddle on the second surface.

20. The carrier of claim 18, wherein the circuit and the column forms a three-dimensional contiguous path with no interface in between.

21. The carrier of claim 18, further comprising a die coupled to the first or second surface.

22. The carrier of claim 21, wherein the die is covered.

23. The carrier of claim 22, further comprising a solder ball on the column and multiple carriers stacked together such that a columns are in communication through the solder ball.

24. The carrier of claim 22, further comprising a solder ball on the column.

25. The carrier of claim 18, wherein a common material of the circuit and column are in communication.

26. The carrier of claim 18, wherein the column is solid.
